(19) United States
(12) Patent Application Publication
(10) Pub. No.: US 2008/0246061 A1
(43) Pub. Date: Oct. 9, 2008

(54) STRESS LAYER STRUCTURE

(75) Inventors: Chin-Sheng Yang, Hsinchu (TW); Chih-Chien Liu, Taipei City (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/695,761

(22) Filed: Apr. 3, 2007

(51) Int. Cl. H01L 29/76

(52) U.S. Cl. 257/288

(57) ABSTRACT

A stress layer structure disposed on a substrate including a device region and a non-device region is provided. The device region includes active regions and a non-active region. The stress layer structure has stress patterns, at least one partition line, and at least one dummy stress pattern. Each of the stress patterns is disposed on the substrate of each of the active regions, respectively. The partition line exposes a portion of the substrate and divides the two adjacent stress patterns. The dummy stress pattern is disposed on the substrate in the partition line.

### BACKGROUND OF THE INVENTION

1. Field of the Invention

The present invention relates to a stress layer structure, and more particularly to a stress layer structure capable of releasing undue stresses.

2. Description of Related Art

As the technological progress leads semiconductor fabrication into the deep sub-micron era, the demand for increasing the driving current of an N-type metal oxide semiconductor (NMOS) transistor and a P-type metal oxide semiconductor (PMOS) transistor is currently on the rise. To be more specific, in the present technology of fabrication process involving a feature size below 65 nm, the effective improvement of the driving current of the NMOS and the PMOS greatly reduces time delay and raises the processing speed of the device.

In the recent years, various proposals to increase the driving current of the device with use of an internal stress have been addressed in the industry. The most common solution is to form a stress layer on both the NMOS transistor and the PMOS transistor. As a tensile stress of the stress layer increases, the driving current at a channel region of the NMOS is then raised. Likewise, as a compressive stress of the stress layer increases, the driving current at the channel region of the PMOS is then raised.

However, the increase in the stress of the stress layer often brings about the fracture of the stress layer due to undue stresses. Simultaneously, particles are formed when the stress layer cracks. Moreover, the increase in the stress of the stress layer leads to peeling of the stress layer in a high stress region or at the of the stress layer. All of the defects presented above deteriorate the performance of the semiconductor devices and further decrease yield of products.

### SUMMARY OF THE INVENTION

Accordingly, the present invention is directed to a stress layer structure capable of releasing undue stresses effectively.

The present invention is further directed to a stress layer structure capable of preventing the stress layer structure from cracking, peeling off, or producing particles.

The present invention is further directed to a stress layer structure capable of improving yield of products.

The present invention provides a stress layer structure disposed on a substrate including a device region and a non-device region. The device region includes a plurality of active regions and a non-active region. The stress layer structure has a plurality of stress patterns, at least a partition line, and at least a dummy stress pattern. Each of the stress patterns is disposed on the substrate of each of the active regions, respectively. The partition line exposes a portion of the substrate and divides the two adjacent stress patterns. The dummy stress pattern is disposed on the substrate in the partition line.

According to the stress layer structure provided in one embodiment of the present invention, the material of the stress patterns includes silicon nitride.

According to the stress layer structure provided in one embodiment of the present invention, the material of the dummy stress pattern includes silicon nitride.

According to the stress layer structure provided in one embodiment of the present invention, said dummy stress pattern is further disposed on the substrate of the non-device region.

According to the stress layer structure provided in one embodiment of the present invention, the substrate of the non-device region includes a polysilicon conductive line, and said dummy stress pattern is further disposed on the polysilicon conductive line.

According to the stress layer structure provided in one embodiment of the present invention, the substrate of the non-device region includes the polysilicon conductive line, and said dummy stress pattern is further disposed on a part of the polysilicon conductive line.

According to the stress layer structure provided in one embodiment of the present invention, each of the active regions includes a MOS transistor region and a non-MOS transistor region, and the stress layer structure further includes a dummy opening disposed in each of the stress patterns of the non-MOS transistor region.

According to the stress layer structure provided in one embodiment of the present invention, the area of the dummy stress pattern occupies 1%˜99% of the total area of the substrate.

The present invention provides another stress layer structure disposed on a substrate including a device region and a non-device region. The device region includes an active region and a non-active region. The active region includes a MOS transistor region and a non-MOS transistor region. The stress layer structure has a plurality of stress layers and a plurality of dummy openings. Each of the stress layers is disposed on the substrate of the device region and the non-device region, respectively. The dummy openings are disposed in the stress layers outside the MOS transistor region.

According to the stress layer structure provided in another embodiment of the present invention, the material of the stress layer structure includes silicon nitride.

According to the stress layer structure provided in another embodiment of the present invention, said dummy openings are further disposed on the substrate of the non-MOS transistor region.

According to the stress layer structure provided in another embodiment of the present invention, said dummy openings are further disposed at the corner of each of the stress layers.

According to the stress layer structure provided in another embodiment of the present invention, the substrate of the non-device region includes a polysilicon conductive line, and each of the dummy openings is further disposed on the polysilicon conductive line.

According to the stress layer structure provided in another embodiment of the present invention, the substrate of the non-device region includes the polysilicon conductive line, and each of the dummy openings is further disposed on a part of the polysilicon conductive line.

According to the stress layer structure provided in another embodiment of the present invention, the total area of the dummy openings pattern occupies 1%˜99% of the total area of the substrate.

The present invention further provides a stress layer structure disposed on a substrate including a device region and a non-device region. The device region includes a plurality of active regions and a non-active region. The active regions include an N-type active region and a P-type active region. The stress layer structure includes a plurality of stress patterns, at least a partition line, and a plurality of dummy stress patterns. The stress patterns include at least a tensile stress pattern and at least a compressive stress pattern. The tensile stress pattern is disposed on the substrate of the N-type active region, while the compressive stress pattern is disposed on the substrate of the P-type active region. The partition line exposes a portion of the substrate and divides the two adjacent stress patterns. The dummy stress patterns include at least a dummy tensile stress pattern and at least a dummy compressive stress pattern. The dummy tensile stress pattern is disposed on the substrate in the partition line, and the dummy compressive stress pattern is disposed on the substrate in the partition line as well.

According to the stress layer structure provided in still another embodiment of the present invention, the material of the stress patterns includes silicon nitride.

According to the stress layer structure provided in still another embodiment of the present invention, the material of the dummy stress patterns includes silicon nitride.

According to the stress layer structure provided in still another embodiment of the present invention, said dummy stress pattern is further disposed on the substrate of the non-device region.

According to the stress layer structure provided in still another embodiment of the present invention, the substrate of the non-device region includes a polysilicon conductive line, and said dummy stress pattern is further disposed on the polysilicon conductive line.

According to the stress layer structure provided in still another embodiment of the present invention, the substrate of the non-device region includes the polysilicon conductive line, and said dummy stress pattern is further disposed on a part of the polysilicon conductive line.

According to the stress layer structure provided in still another embodiment of the present invention, each of the active regions includes a MOS transistor region and a non-MOS transistor region, and the stress layer structure further includes a dummy opening disposed in each of the stress patterns of the non-MOS transistor region.

According to the stress layer structure provided in still another embodiment of the present invention, the area of the dummy stress pattern occupies 1%˜99% of the total area of the substrate.

In view of the foregoing, the partition line and the dummy stress pattern are incorporated in the stress layer structure provided by the present invention. Thus, undue stresses in the stress layer can be effectively released, preventing the stress layer from cracking, peeling off, or producing particles.

In addition, the stress layer structure provided by the present invention includes a plurality of the dummy openings, through which undue stresses in the stress layer can be released. The occurrence of defects can then be avoided and yield of products is further improved.

Moreover, the dummy stress patterns in the stress layer structure are well distributed to the regions requiring no stresses. Accordingly, uniformity of etching and that of stresses can be improved.

In order to the make the aforementioned and other objects, features and advantages of the present invention comprehensible, a preferred embodiment accompanied with figures are described in detail below.

### BRIEF DESCRIPTION OF THE DRAWINGS

FIG. 1 is a top view of a stress layer structure according to a first embodiment of the present invention.

FIG. 2 is a top view of a stress layer structure according to a second embodiment of the present invention.

FIG. 3 is a top view of a stress layer structure according to a third embodiment of the present invention.

### DESCRIPTION OF EMBODIMENTS

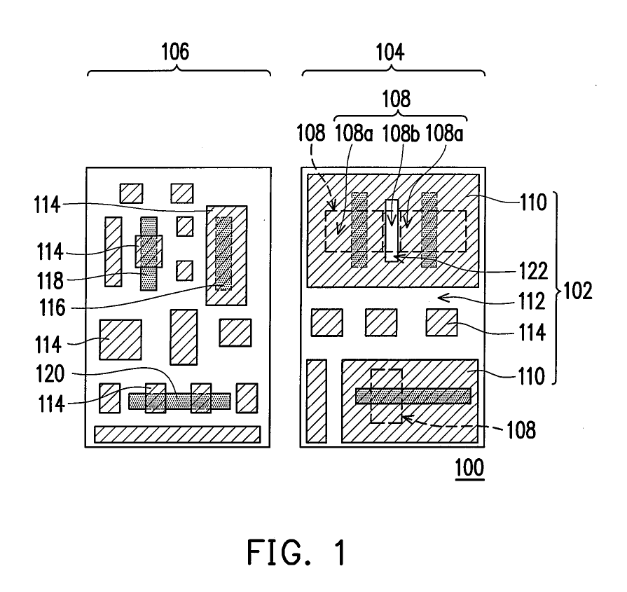

FIG. 1 is a top view of a stress layer structure according to a first embodiment of the present invention that shows the application of pressure-adjusting stress blocks on the stress layer.

Referring to FIG. 1, the stress layer structure 102 is disposed on the substrate 100 including a device region 104 and a non-device region 106. The non-device region 106 is, for example, a shallow trench isolation (STI) structure.

The device region 104 includes a plurality of active regions 108 and a non-active region (the region other than the active regions 108 in the device region 104, not shown). The active regions 108 are designed based on required active devices. When the required active devices are NMOSs, the active regions 108 are correspondingly designed as N-type active regions. On the other hand, when the required active devices are PMOSs, the active regions 108 are then designed as P-type active regions.

The stress layer structure 102 includes a plurality of stress patterns 110, at least a partition line 112, and at least a dummy stress pattern 114.

Each of the stress patterns 110 is disposed on the substrate 100 of each of the active regions 108, respectively. The definition of the stress patterns 110 is that the stress patterns 110 are disposed at least on the active regions 108 requiring stresses. The material of the stress patterns 110 is, for example, nitride silicon. The stress patterns 110 can be tensile stress patterns or compressive stress patterns, depending on the types of the active regions 108 e.g. the N-type active regions or the P-type active regions.

The partition line 112 exposes a portion of the substrate 100 and divides the two adjacent stress patterns 110, such that no stress patterns 110 exist in the partition line 112.

The dummy stress pattern 114 is disposed on the substrate 100 in the partition line 112. The definition of the dummy stress pattern 114 is: the dummy stress pattern 114 is disposed on the non-active region 108 requiring no stresses. The material of the dummy stress pattern 114 is, for example, nitride silicon. The dummy stress pattern 114 can be the dummy tensile stress pattern or the dummy compressive stress pattern, depending on the types of the active regions 108 e.g. the N-type active regions or the P-type active regions. The dummy stress pattern 114 and the stress patterns 110 are simultaneously formed, for example.

In addition, the dummy stress pattern 114 is further disposed on the substrate 100 of the non-active region 106. For example, the substrate 100 in the non-device region 106 includes polysilicon conductive lines 116, 118, and 120. The dummy stress pattern 114 can be further disposed on the polysilicon conductive line 116 and on parts of the polysilicon conductive lines 118 and 120. The area of said dummy stress pattern 114, for example, occupies 1%˜99% of the total area of the substrate 100.

Moreover, each of the active regions 108 can be divided into a MOS transistor region 108a and a non-MOS transistor region 108b, and the stress layer structure 102 further includes a plurality of dummy openings 122 disposed in the stress patterns 110 of the non-MOS transistor region 108b.

In view of the first embodiment, the partition line 112 and the dummy stress pattern 114 are incorporated in the stress layer structure 102. Thus, undue stresses in the stress layer can be effectively released or the region lacked of stress can be balanced, preventing the stress layer from cracking and peeling off to avoid producing particles. Furthermore, the dummy openings 122 disposed in the stress patterns 110 of the non-MOS transistor region 108b are conducive to releasing the stresses in the stress layer.

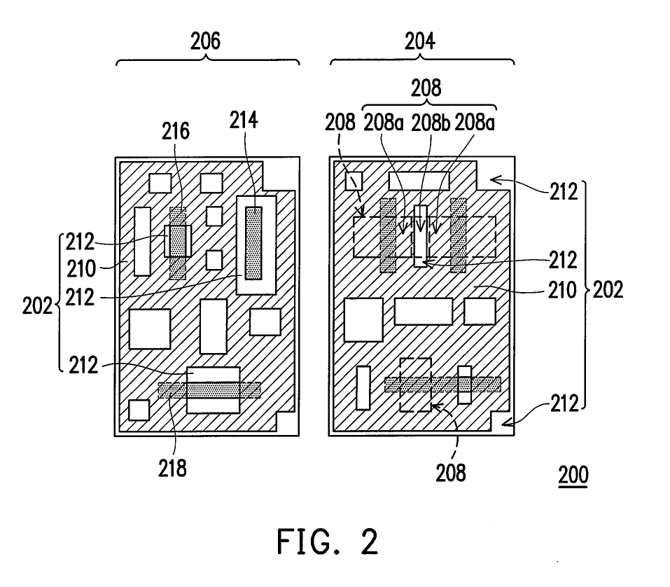

FIG. 2 is a top view of a stress layer structure according to a second embodiment of the present invention that shows the application of pressure-releasing openings on the stress layer.

Referring to FIG. 2, the stress layer structure 202 is disposed on a substrate 200 including a device region 204 and a non-device region 206. The non-device region 206 is, for example, a shallow trench isolation (STI) structure.

The device region 204 includes a plurality of active regions 208 and a non-active region (the region other than the active regions 208 in the device region 204, not shown). The active regions 208 are designed based on required active devices. When the required active devices are NMOSs, the active regions 208 are correspondingly designed as N-type active regions. On the other hand, when the required active devices are PMOSs, the active regions 208 are then designed as P-type active regions. Each of the active regions 208 includes a MOS transistor region 208a and a non-MOS transistor region 208b.

The stress layer structure 202 has a plurality of stress layers 210 and a plurality of dummy openings 212.

Each of the stress layers 210 is disposed on the substrate 200 of the device region 204 and of the non-device region 206, respectively. The material of the stress layers 210 is, for example, silicon nitride. The stress layers 210 can be tensile stress patterns or compressive stress patterns, depending on the types of the active regions 208, for example, the N-type active regions or the P-type active regions.

The dummy openings 212 are disposed in the stress layers 210 outside the MOS transistor region 208a. For example, the dummy openings 212 are further disposed in the non-MOS transistor region 208b or at the corner of each of the stress layers 210.

In addition, the dummy openings 212 are further disposed on the substrate 200 in the non-active region 206. For example, the substrate 200 in the non-device region 206 includes polysilicon conductive lines 214, 216, and 218. The dummy openings 212 can be further disposed on the polysilicon conductive line 214 and on parts of the polysilicon conductive lines 216 and 218. The total area of said dummy openings 212, for example, occupies 1%˜99% of the total area of the substrate 200.

Based on said second embodiment, the stress layer structure 202 includes a plurality of the dummy openings 212 through which undue stresses in the stress layers 210 can be released. The occurrence of defects in the stress layers 210 can then be avoided and yield of products is further improved.

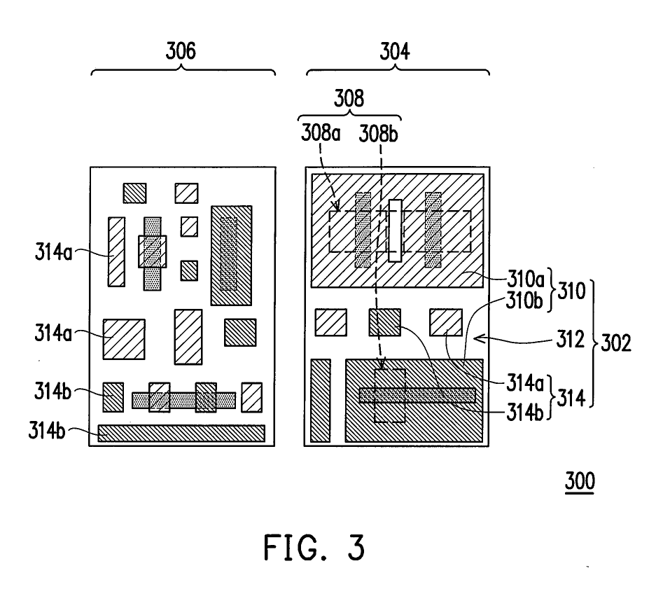

FIG. 3 is a top view of a stress layer structure according to a third embodiment of the present invention that shows the mixed application of pressure-releasing openings and pressure-adjusting stress blocks on the stress layer.

Referring to FIG. 3, the stress layer structure 302 is disposed on the substrate 300 including a device region 304 and a non-device region 306. The non-device region 306 is, for example, a shallow trench isolation (STI) structure.

The device region 304 includes a plurality of active regions 308 and a non-active region (the region other than the active regions 308 in the device region 304, not shown). The active regions 308 including N-type active regions 308a and P-type active regions 308b are designed based on required active devices. When the required active devices are NMOSs, the active regions 308 are correspondingly designed as the N-type active regions 308a. On the other hand, when the required active devices are PMOSs, the active regions 308 are then designed as the P-type active regions 308b.

The stress layer structure 302 includes a plurality of stress patterns 310, at least a partition line 312, and a plurality of dummy stress patterns 314.

The definition of the stress patterns 310 is that the stress patterns 310 are disposed at least on the active regions 308 requiring stresses. The stress patterns 310 include at least a tensile stress pattern 310a and at least a compressive stress pattern 310b. The tensile stress pattern 310a having a tensile stress is disposed on the substrate 300 of the N-type active regions 308a. On the other hand, the compressive stress pattern 310b having a compressive stress is disposed on the substrate 300 of the P-type active regions 308b. The material of the stress patterns 310 is, for example, nitride silicon.

The partition line 312 exposes a portion of the substrate 310 and divides the two adjacent stress patterns 310, such that no stress patterns 310 exist in the partition line 312.

The definition of the dummy stress pattern 314 is that the dummy stress pattern 314 is disposed on the non-active region requiring no stresses. The dummy stress patterns 314 include at least a dummy tensile stress pattern 314a and at least a dummy compressive stress pattern 310b. The dummy tensile stress pattern 314a having the tensile stress is disposed on the substrate 300 in the partition line 312. Likewise, the dummy compressive stress pattern 314b having the compressive stress is disposed on the substrate 300 in the partition line 312. The material of the dummy stress patterns 314 is, for example, nitride silicon. The dummy stress patterns 314 and the stress patterns 310 are simultaneously formed, for example. The total area of said dummy stress patterns 314, for example, occupies 1%˜99% of the total area of the substrate 300. The arrangement of said dummy stress patterns 314 is roughly the same as that of the dummy stress patterns 114 according to the first embodiment in FIG. 1. Thus, no further description is provided hereinafter.

It should be noted that the dummy tensile stress pattern 314a and the dummy compressive stress pattern 314b are distributed to the non-active regions requiring no stresses according to the third embodiment. Accordingly, uniformity of etching and that of stresses can be improved.

In summary, the present invention has at least the following advantages:

1. The stress layer structure provided by the present invention is capable of releasing undue stresses to prevent the stress layer from the damage of producing particles caused by the stress layer cracking or peeling off and further improving yield of products.

2. The stress layer structure provided by the present invention is capable of raising uniformity of etching and of stresses.

What is claimed is:

1. A stress layer structure disposed on a substrate comprising a device region and a non-device region, the device region comprising a plurality of active regions and a non-active region, the stress layer structure comprising:
a plurality of stress patterns disposed on the substrate of each of the active regions, respectively;
at least a partition line exposing a portion of the substrate and dividing the two adjacent stress patterns; and
at least a dummy stress pattern disposed on the substrate in said partition line.

2. The stress layer structure of claim 1, wherein the material of the stress patterns comprises silicon nitride.

3. The stress layer structure of claim 1, wherein the material of said dummy stress pattern comprises silicon nitride.

4. The stress layer structure of claim 1, wherein said dummy stress pattern is further disposed on the substrate of the non-device region.

5. The stress layer structure of claim 1, wherein the substrate of the non-device region comprises a polysilicon conductive line, and said dummy stress pattern is further disposed on the polysilicon conductive line.

6. The stress layer structure of claim 1, wherein the substrate of the non-device region comprises the polysilicon conductive line, and said dummy stress pattern is further disposed on a part of the polysilicon conductive line.

7. The stress layer structure of claim 1, wherein each of the active regions comprises a MOS transistor region and a non-MOS transistor region, and the stress layer structure further comprises a dummy opening disposed in each of the stress patterns of the non-MOS transistor region.

8. The stress layer structure of claim 1, wherein the area of said dummy stress pattern occupies 1%˜99% of the total area of the substrate.

9. A stress layer structure disposed on a substrate comprising a device region and a non-device region, the device region comprising an active region and a non-active region, the active region comprising a MOS transistor region and a non-MOS transistor region, the stress layer structure comprising:
a plurality of stress layers disposed on the substrate of the device region and of the non-device region, respectively; and
a plurality of dummy openings disposed in the stress layers outside the MOS transistor region.

10. The stress layer structure of claim 9, wherein the material of the stress layers comprises silicon nitride.

11. The stress layer structure of claim 9, wherein each of the dummy openings is further disposed in the non-MOS transistor region.

12. The stress layer structure of claim 9, wherein each of the dummy openings is further disposed at the corner of each of the stress layers.

13. The stress layer structure of claim 9, wherein the substrate of the non-device region comprises a polysilicon conductive line, and each of the dummy openings is further disposed on the polysilicon conductive line.

14. The stress layer structure of claim 9, wherein the substrate of the non-device region comprises the polysilicon conductive line, and each of the dummy openings is further disposed on a part of the polysilicon conductive line.

15. The stress layer structure of claim 9, wherein the total area of the dummy openings occupies 1%˜99% of the total area of the substrate.

16. A stress layer structure disposed on a substrate comprising a device region and a non-device region, the device region comprising a plurality of active regions and a non-active region, the active regions comprising an N-type active region and a P-type active region, the stress layer structure comprising:
a plurality of stress patterns, comprising:
at least a tensile stress pattern disposed on the substrate of the N-type active region; and
at least a compressive stress pattern disposed on the substrate of the P-type active region;
at least a partition line dividing the two adjacent stress patterns; and
a plurality of dummy stress patterns, comprising:
at least a dummy tensile stress pattern disposed on the substrate in said partition line; and
at least a dummy compressive stress pattern disposed on the substrate in said partition line.

17. The stress layer structure of claim 16, wherein the material of the stress patterns comprises silicon nitride.

18. The stress layer structure of claim 16, wherein the material of the dummy stress patterns comprises silicon nitride.

19. The stress layer structure of claim 16, wherein each of the dummy stress patterns is further disposed on the substrate of the non-device region.

20. The stress layer structure of claim 16, wherein the substrate of the non-device region comprises a polysilicon conductive line, and each of the dummy stress patterns is further disposed on the polysilicon conductive line.

21. The stress layer structure of claim 16, wherein the substrate of the non-device region comprises the polysilicon conductive line, and each of the dummy stress patterns is further disposed on a part of the polysilicon conductive line.

22. The stress layer structure of claim 16, wherein each of the active regions comprises a MOS transistor region and a non-MOS transistor region, and the stress layer structure further comprises a dummy opening disposed in each of the stress patterns of the non-MOS transistor region.

23. The stress layer structure of claim 16, wherein the area of the dummy stress patterns occupies 1%˜99% of the total area of the substrate.
